(19) United States
(12) Patent Application Publication
(10) Pub. No.: US 2014/0264865 A1
(43) Pub. Date: Sep. 18, 2014

(54) SEMICONDUCTOR DEVICE AND MANUFACTURING METHOD THEREOF

(71) Applicant: INFINEON TECHNOLOGIES AG, Neubiberg (DE)

(72) Inventors: Manfred Schneegans, Vaterstetten (DE); Juergen Foerster, Tegernheim (DE)

(73) Assignee: Infineon Technologies AG, Neubiberg (DE)

(21) Appl. No.: 13/803,988

(22) Filed: Mar. 14, 2013

(51) Int. Cl. H01L 23/532; H01L 21/768

(52) U.S. Cl. CPC H01L 23/53238; H01L 21/7685
USPC 257/751; 438/627

(57) ABSTRACT

A semiconductor device may include: a barrier layer; an adhesion layer disposed over the barrier layer; a metallization layer disposed over the adhesion layer, wherein the metallization layer is part of a final metallization level of the semiconductor device.

### TECHNICAL FIELD

Various embodiments relate to a semiconductor device and a manufacturing method thereof.

### BACKGROUND

Power metallisation systems employed in semiconductor devices, e.g. power semiconductor devices such as power transistors, may frequently be deposited by electrochemical pattern plating. In such devices, a diffusion barrier layer may be provided (e.g. deposited) between a metallization layer and a sublayer of electric or electronic devices (e.g. transistors) so as to prevent diffusion of metal from the metallization layer into the sublayer of electric or electronic devices (e.g. transistors). While such barrier layers may be adequate in preventing the diffusion of metal, such as copper or aluminum, into the sublayer of electric or electronic devices (e.g. transistors), these barrier layers may suffer, for example, from the following drawbacks: a) adhesive strength between the barrier layer and the metallization layer may be weak; and/or b) strong thermo-mechanical stress may be generated inside the interface between the barrier layer and the metallization layer.

Consequently, delamination of the metallization layer from the barrier layer may occur after several cycles of on-off switches. Due to such delamination, the affected device areas (e.g. transistor areas), i.e. the device areas where the metallization has delaminated, may locally overheat, which may lead to burn-out of the affected electric or electronic devices (e.g. transistors), finally resulting in a breakdown of the semiconductor device.

Therefore, there may be a need to provide for a semiconductor device that avoids, or at least alleviates, the above problem.

### SUMMARY

A semiconductor device is provided, which may include: a bather layer; an adhesion layer disposed over (e.g. on) the barrier layer; a metallization layer disposed over (e.g. on) the adhesion layer, wherein the metallization layer is part of a final metallization level of the semiconductor device.

Furthermore, a semiconductor device is provided, which may include: a bather layer containing a first metallic component and a second metallic component; an adhesion layer disposed over (e.g. on) the bather layer and containing the first metallic component and the second metallic component; a metallization layer disposed over (e.g. on) the adhesion layer, wherein a concentration of the second metallic component in the adhesion layer is greater than a concentration of the second metallic component in the barrier layer.

Furthermore, a method for manufacturing a semiconductor device is provided, which may include: depositing a bather layer containing a first metallic component and a second metallic component; depositing an adhesion layer over (e.g. on) the bather layer, the adhesion layer containing the first metallic component and the second metallic component, wherein a concentration of the second metallic component in the adhesion layer is greater than a concentration of the second metallic component in the bather layer; and depositing a metallization layer over (e.g. on) the adhesion layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a semiconductor device according to various embodiments.

FIG. 1B shows a method for manufacturing a semiconductor device according to various embodiments.

FIGS. 2A to 2D show a method for manufacturing a semiconductor device according to various embodiments.

### DESCRIPTION

The following detailed description refers to the accompanying drawings that show, by way of illustration, specific details and embodiments in which the invention may be practised. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. Various embodiments are described in connection with methods and various embodiments are described in connection with devices. However, it may be understood that embodiments described in connection with methods may similarly apply to the devices, and vice versa.

The word “exemplary” is used herein to mean “serving as an example, instance, or illustration”. Any embodiment or design described herein as “exemplary” is not necessarily to be construed as preferred or advantageous over other embodiments or designs.

The terms “at least one” and “one or more” may be understood to include any integer number greater than or equal to one, i.e. one, two, three, four, etc.

The term “a plurality” may be understood to include any integer number greater than or equal to two, i.e. two, three, four, five, etc.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

Various embodiments relate to a semiconductor device and various embodiments relate to a method for manufacturing a semiconductor device.

In accordance with one or more embodiments, an adhesion layer may be formed (e.g. by means of deposition) between a barrier layer (e.g. diffusion bather against metal diffusion, e.g. Cu and/or Al diffusion) and a metallization layer of a semiconductor device (e.g. power semiconductor device, e.g. power transistor). In one or more embodiments, the metallization layer may be part of a final metallization layer. The adhesion layer may increase adhesion between the metallization layer and the bather layer and thereby prevent, or at least substantially reduce, delamination of the metallization layer from the bather layer. In one or more embodiments, the barrier layer and the adhesion layer may include first and second metallic components, wherein the first metallic component may be a component that predominantly serves for increasing barrier characteristics of a layer, and the second metallic component may be a component that predominantly serves for increasing adhesive characteristics of a layer. In one or more embodiments, a concentration of the second metallic component may be greater in the adhesion layer than in the barrier layer.

In accordance with one or more embodiments, a metallic adhesion layer may be deposited over (e.g. on) the barrier layer, wherein the adhesion layer may be configured to have adjusted good adhesion to both the metallization layer (e.g. power metal) and the barrier layer.

In accordance with one or more embodiments, the adhesion layer may be deposited after the barrier layer deposition in an extra process step.

In accordance with one or more embodiments, the adhesion layer deposition may be performed using the same equipment and, in accordance with some embodiments, using the same process chamber as used for deposition of the barrier layer.

In accordance with one or more embodiments, the metallization layer (e.g. thick power metallization) may, for example, be deposited using a pattern plating process, including depositing a resist layer, patterning the resist layer, and depositing metal over the patterned resist layer by means of plating (electrochemical deposition).

In accordance with one or more embodiments, after deposition of the thick metal, the resist and the adhesion layer and barrier layer between the thick metal lines may be removed by etching, e.g. wet etching.

Structures or devices with, for example, tungsten-titanium barrier and an additional titanium-rich adhesion layer may, for example, exhibit less delamination after up to 12 million thermal cycles, compared to standard barrier-power metal systems.

Samples with modified stoichiometry or reactive sputtering by nitrogen or other inert gases, e.g. xenon, may e.g. be used to adjust the adhesion properties between barrier and power metal.

FIG. 1A shows a semiconductor device 110 according to one embodiment. The semiconductor device 110 may include: a bather layer 112; an adhesion layer 114 disposed on the barrier layer 112; a metallization layer 116 disposed over the adhesion layer 114, wherein the metallization layer 116 is part of a final metallization level of the semiconductor device 110.

Optionally, the semiconductor device 110 may include a seed layer 121, wherein the seed layer 121 may be disposed over (e.g. on) the adhesion layer 114 (as shown). The metallization layer 116 may be disposed on the seed layer 121, if present, (as shown), or on the adhesion layer 114.

The term “final metallization level” may include, or may refer to, e.g. a topmost or last metallization level of one or more metallization levels in a layer arrangement of the semiconductor device. For example, a semiconductor device may include a layer arrangement including metallization levels “Metal-1”, “Metal-2”, “Metal-3”, . . . , “Metal-N”, wherein “Metal-1” may be the lowermost metallization level in the layer arrangement and “Metal-N” may be the topmost metallization level (i.e. the final metallization level) in the layer arrangement.

In various embodiments, the semiconductor device 110 may be configured as a power semiconductor device. For example, the power semiconductor device may be used as a switch or rectifier in power electronics.

In certain embodiments, the semiconductor device 110 may be configured as a power transistor, for example, a power field effect transistor, e.g. a power metal oxide semiconductor field effect transistor, or a power bipolar transistor, e.g. an insulated gate bipolar transistor.

In yet another embodiment, the semiconductor device 110 may be configured as a power diode.

The metallization layer 116 is an electrically conductive layer and may, for example, be adapted for conducting high power currents in a power semiconductor device.

Thus, in various embodiments, the metallization layer 116 may include an electrically conductive material, for example at least one material selected from a group of materials, the group consisting of: a metal, a metal alloy, and a combination thereof.

In certain embodiments, the metallization layer 116 may include at least one material selected from a group of materials, the group consisting of: copper (Cu), aluminum (Al), a copper alloy, an aluminum alloy, and a combination thereof.

In one embodiment, the metallization layer 116 may include Cu.

In another embodiment, the metallization layer 116 may include Al.

The metallization layer 116 may have a thickness selected to be sufficient to conduct high power currents, for example, in a power semiconductor device.

Thus, in various embodiments, the metallization layer 116 may have a thickness of greater than or equal to about 1 μm. For example, the metallization layer 116 may have a thickness greater than or equal to about 2 μm, for example greater than or equal to about 5 μm, e.g. in the range from about 1 μm to about 30 μm, e.g. in the range from about 2 μm to about 30 μm, e.g. in the range from about 5 μm to about 30 μm.

The optional seed layer 121 may facilitate growth of the metallization layer 116. The seed layer 121 may include or may consist of the same material as the metallization layer 116.

The bather layer 112 may be a diffusion barrier layer. The bather layer 112 may prevent diffusion of the electrically conductive material (e.g. metal or metal alloy) present in the metallization layer 116, for example, copper or aluminum, into a layer located away from the metallization layer 116 and the adhesion layer 114, e.g. a layer located below the barrier layer 112.

As illustrated in FIG. 1A, the semiconductor device 110 may further include a layer (or layer stack) 119 including one or more electric or electronic devices (e.g. transistors) 118 disposed below the barrier layer 112. In other words, the barrier layer 112 may be disposed over (e.g. on) the layer (or layer stack) 119. In one or more embodiments, the optional seed layer 121 may be disposed between the adhesion layer 114 and the metallization layer 116, as shown. The barrier layer 112 may be disposed between the metallization layer 116 and the layer (or layer stack) 119 including the one or more electric or electronic devices (e.g. transistors) 118 and may therefore prevent the diffusion of the electrically conductive material (e.g. metal or metal alloy) present in the metallization layer 116 into the layer (or layer stack) 119 including the one or more electric or electronic devices (e.g. transistors) 118. The layer (or layer stack) 119 including the one or more electric or electronic devices (e.g. transistors) 118 may, for example, be part of a carrier or substrate (e.g. semiconductor carrier or substrate, e.g. silicon substrate) or may be disposed over the carrier or substrate.

In various embodiments, the barrier layer 112 may include at least one material selected from a group of materials, the group consisting of: a metal, a metal alloy, and a combination thereof.

In various embodiments, the barrier layer 112 may include a first metallic component and a second metallic component. The second metallic component may be different from the first metallic component.

In one embodiment, the bather layer 112 may include tungsten (W). For example, one of the first and second metallic components may be tungsten.

In another embodiment, the barrier layer 112 may include tungsten (W) and titanium (Ti). For example, the first metallic component may be tungsten, and the second metallic component may be titanium.

In certain embodiments, the first metallic component of the bather layer 112 may be selected from a group of metallic components, the group consisting of: tungsten (W), tantalum (Ta), tantalum nitride (TaN), and molybdenum (Mo).

In certain embodiments, the second metallic component of the bather layer 112 may be selected from a group of metallic components, the group consisting of: titanium (Ti), tantalum (Ta), nickel (Ni), and titanium silicide (e.g. titanium disilicide (TiSi₂)).

In exemplary embodiments, the barrier layer 112 may include at least one material selected from a group of materials, the group consisting of: WTi, TaTi, MoTi, WTa, and a combination thereof.

In one or more embodiments, the bather layer 112 may have a thickness of less than or equal to about 500 nm. For example, the bather layer 112 may have a thickness in the range from about 50 nm to about 500 nm, e.g. in the range from about 150 nm to about 300 nm, e.g. a thickness of about 200 nm.

The adhesion layer 114 may be disposed between the barrier layer 112 and the metallization layer 116. The adhesion layer 114 sandwiched between the bather layer 112 and the metallization layer 116 may be configured to prevent delamination of the metallization layer 116 from the barrier layer 112 by improving the adhesion therebetween. In other words, the adhesion layer 114 may increase adhesion of the metallization layer 116 to the barrier layer 112, thus preventing delamination of the metallization layer 116. The metallization layer 116 may be said to have at least partially delaminated from the barrier layer 112 when one or more portions of the metallization layer 116 are no longer in contact, either directly or indirectly, with the barrier layer 112.

The adhesion layer 114 may also act to reduce the thermo-mechanical stress inside the interface between the barrier layer 112 and the metallization layer 116.

Thus, in various embodiments, the adhesion layer 114 may include or may be composed of a material that has a stronger adhesion to the metallization layer 116 than a material of the barrier layer 112. A material may be said to have a stronger adhesion than another material when a larger force is required to delaminate the material from a surface the material is adhered to.

In certain embodiments, the adhesion layer 114 may include a first metallic component and a second metallic component. The second metallic component may be different from the first metallic component.

In certain embodiments, the first metallic component of the adhesion layer 114 may be selected from a group of metallic components, the group consisting of: W, Ta, TaN, and Mo.

In certain embodiments, the second metallic component of the adhesion layer 114 may be selected from a group of metallic components, the group consisting of: Ti, Ta, Ni, and titanium silicide (e.g. TiSi₂).

In exemplary embodiments, the adhesion layer 114 may include at least one material selected from a group of materials, the group consisting of: WTi, TaTi, MoTi, WTa, and a combination thereof.

In one or more embodiments, the bather layer 112 and the adhesion layer 114 each may include a first metallic component and a second metallic component. That is, the bather layer 112 and adhesion layer 114 may include the same first metallic component and the same second metallic component. A concentration of the second metallic component in the adhesion layer 114 may be greater than a concentration of the second metallic component in the bather layer 112, wherein an increase in concentration of the second metallic component in a layer may increase adhesion of that layer to the metallization layer 116. Thus, the adhesion layer 114 having a greater concentration of the second metallic component than the bather layer 112 may have a greater adhesion to the metallization layer 116 than the barrier layer 112 would have.

In certain embodiments, the first metallic component of the bather layer 112 and the adhesion layer 114 may be selected from a group of metallic components, the group consisting of: W, Ta, TaN, and Mo.

In certain embodiments, the second metallic component of the barrier layer 112 and the adhesion layer 114 may be selected from a group of metallic components, the group consisting of: Ti, Ta, Ni, and titanium silicide (e.g. TiSi₂).

In various embodiments, a concentration of the second metallic component in the bather layer 112 may be greater than zero and less than or equal to about 20 at. % (atomic percent), and a concentration of the second metallic component in the adhesion layer 114 may be greater than about 30 at. %. For example, a concentration of the second metallic component in the bather layer 112 may be in the range from about 10 at. % to about 20 at. %, and a concentration of the second metallic component in the adhesion layer 114 may be in the range from about 30 at. % to about 40 at. %.

In one or more embodiments, the bather layer 112 and the adhesion layer 114 may include WTi, TaTi, or MoTi (that is, the first metallic component may be W, Ta, or Mo, and the second metallic component may be Ti), and a concentration of Ti (second metallic component) in the bather layer 112 may be less than or equal to about 20 at. %, for example in the range from about 10 at. % to about 20 at. %, and a concentration of Ti (second metallic component) in the adhesion layer 114 may be greater than about 30 at. %, for example in the range from about 30 at. % to about 40 at. %.

In one or more embodiments, the adhesion layer 114 may have a thickness of less than or equal to about 100 nm. For example, the adhesion layer 114 may have a thickness in the range from about 10 nm to about 100 nm, e.g. in the range from about 25 nm to about 75 nm, e.g. a thickness of about 50 nm.

Various embodiments further relate to a semiconductor device, which may include: a bather layer containing a first metallic component and a second metallic component; an adhesion layer disposed on the bather layer and containing the first metallic component and the second metallic component; a metallization layer disposed over (e.g. on) the adhesion layer, wherein a concentration of the second metallic component in the adhesion layer is greater than a concentration of the second metallic component in the bather layer.

In one or more embodiments, the semiconductor device may include a seed layer disposed over (e.g. on) the adhesion layer. The metallization layer may be disposed on the seed layer. The seed layer may facilitate growth of the metallization layer. The seed layer may include or may consist of the same material as the metallization layer.

In certain embodiments, an increase in concentration of the second metallic component in a layer may increase adhesion of that layer to the metallization layer. Thus, the adhesion layer having a greater concentration of the second metallic component than the bather layer may have a greater adhesion to the metallization layer than the barrier layer would have.

In various embodiments, the metallization layer may include an electrically conductive material.

In various embodiments, the metallization layer may include at least one material selected from a group of materials, the group consisting of: a metal, a metal alloy, and a combination thereof.

In exemplary embodiments, the metallization layer may include at least one material selected from a group of materials, the group consisting of: copper, aluminum, a copper alloy, an aluminum alloy, and a combination thereof.

In various embodiments, the metallization layer may have a thickness of greater than or equal to about 1 μm, for example greater than or equal to about 2 μm, for example greater than or equal to about 5 μm, e.g. in the range from about 1 μm to about 30 μm, e.g. in the range from about 2 μm to about 30 μm, e.g. in the range from about 5 μm to about 30 μm.

In one or more embodiments, the metallization layer may be part of a final metallization level of the semiconductor device.

In various embodiments, the semiconductor device may be configured as a power semiconductor device. For example, the power semiconductor device may be used as a switch or rectifier in power electronics.

In certain embodiments, the semiconductor device may be configured as a power transistor, for example, a power field effect transistor, e.g. a power metal oxide semiconductor field effect transistor, or a power bipolar transistor, e.g. an insulated gate bipolar transistor.

In yet another embodiment, the semiconductor device may be configured as a power diode.

In various embodiments, the second metallic component may be different from the first metallic component, and therefore impart different characteristics to the respective layer. For example, the first metallic component may be a component that predominantly serves for increasing bather characteristics of a layer, and the second metallic component may be a component that predominantly serves for increasing adhesive characteristics of a layer.

In one or more embodiments, the first metallic component may be selected from a group of metallic components, the group consisting of: W, Ta, TaN, Mo; and the second metallic component may be selected from a group of metallic components, the group consisting of: Ti, Ta, Ni, titanium silicide (e.g. TiSi₂).

In certain embodiments, the concentration of the second metallic component in the bather layer may be greater than zero and less than or equal to about 20 at. %, and the concentration of the second metallic component in the adhesion layer may be greater than about 30 at. %. For example, the concentration of the second metallic component in the bather layer may be in the range from about 10 at. % to about 20 at. %, and the concentration of the second metallic component in the adhesion layer may be in the range from about 30 at. % to about 40 at. %.

In one embodiment, the first metallic component may be W, Ta, or Mo, and the second metallic component may be Ti.

The bather layer may be a diffusion bather layer. The barrier layer may serve to prevent diffusion of the electrically conductive material (e.g. metal or metal alloy) present in the metallization layer, for example, copper or aluminum, into a layer located away from the metallization layer and the adhesion layer, e.g. a layer located below the barrier layer.

In various embodiments, the barrier layer may have a thickness of less than or equal to about 500 nm, for example in the range from about 50 nm to about 500 nm, e.g. in the range from about 150 nm to about 300 nm, e.g. a thickness of about 200 nm.

In various embodiments, the adhesion layer may have a thickness of less than or equal to about 100 nm, for example in the range from about 10 nm to about 100 nm, e.g. in the range from about 25 nm to about 75 nm, e.g. a thickness of about 50 nm.

In one or more embodiments, the semiconductor device may include a layer or layer stack, e.g. a semiconductor layer (e.g. silicon layer) or a layer stack including a semiconductor layer (e.g. silicon layer), e.g. a carrier or substrate (e.g. semiconductor carrier or substrate, e.g. silicon substrate), wherein the barrier layer may be disposed over (e.g. on) the layer or layer stack. In other words, the layer or layer stack may be located below the barrier layer.

FIG. 1B shows a method 150 for manufacturing a semiconductor device in accordance with various embodiments. The method 150 may include: depositing a barrier layer containing a first metallic component and a second metallic component (in 152); depositing an adhesion layer on the barrier layer, the adhesion layer containing the first metallic component and the second metallic component, wherein a concentration of the second metallic component in the adhesion layer is greater than a concentration of the second metallic component in the barrier layer (in 154); and depositing a metallization layer over (e.g. on) the adhesion layer (in 156).

In one or more embodiments, the method may further include depositing a seed layer over (e.g. on) the adhesion layer before depositing the metallization layer, and depositing the metallization layer over the adhesion layer may include depositing the metallization layer on the seed layer. The seed layer may facilitate growth of the metallization layer. The seed layer may include or may consist of the same material as the metallization layer. Depositing the seed layer may include a vapor deposition process, e.g. a physical vapor deposition (PVD) process or chemical vapor deposition (CVD) process, or a sputter deposition process, or the like.

The semiconductor device may be configured as a power semiconductor device such as a power transistor, for example, a power field effect transistor, e.g. a power metal oxide semiconductor field effect transistor, or a power bipolar transistor, e.g. an insulated gate bipolar transistor. Alternatively, the semiconductor device may be configured as a power diode.

The second metallic component may be different from the first metallic component. In one or more embodiments, the first metallic component may be selected from a group of metallic components, the group consisting of: W, Ta, TaN, and Mo; and the second metallic component may be selected from a group of metallic components, the group consisting of: Ti, Ta, Ni, and titanium silicide (e.g. TiSi₂).

The metallization layer may include at least one electrically conductive material. The metallization layer may include at least one material selected from a group of materials, the group consisting of: a metal, a metal alloy, and a combination thereof. For example, the metallization layer may include at least one material selected from a group of materials, the group consisting of: copper (Cu), aluminum (Al), a copper alloy, an aluminum alloy, and a combination thereof.

In various embodiments, an increase in concentration of the second metallic component in a layer may increase adhesion of that layer to the metallization layer. Thus, the adhesion layer having a greater concentration of the second metallic component than the bather layer may have a greater adhesion to the metallization layer than the barrier layer would have.

In one or more embodiments, the concentration of the second metallic component in a layer may be given by its atomic percent (at. %), which may indicate the percentage of one kind of atom relative to the total number of atoms in the layer. In certain embodiments, the concentration of the second metallic component in the bather layer may be greater than zero and less than or equal to about 20 at. %, and the concentration of the second metallic component in the adhesion layer may be greater than about 30 at. %. For example, the concentration of the second metallic component in the barrier layer may be in the range from about 10 at. % to about 20 at. %, and the concentration of the second metallic component in the adhesion layer may be in the range from about 30 at. % to about 40 at. %.

In various embodiments, depositing the adhesion layer may include using the same deposition equipment as used for depositing the bather layer, and varying at least one deposition parameter to obtain an increased concentration of the second metallic component in the adhesion layer compared to the concentration of the second metallic component in the bather layer. For example, the at least one deposition parameter may be the rate of deposition of the second metallic component, the amount of second metallic component to be deposited, or the duration of deposition of the second metallic component.

In various embodiments, depositing the adhesion layer may include using the same process chamber as used for depositing the barrier layer. Alternatively, the process chamber for depositing the adhesion layer may be different from the process chamber for deposition of the bather layer.

Depositing the barrier layer may include a vapor deposition process, e.g. a physical vapor deposition (PVD) process, a chemical vapor deposition (CVD) process, a low-pressure CVD (LPCVD) process, a plasma-enhanced CVD (PECVD) process, or a high-density plasma CVD (HPD-CVD) process.

Alternatively, depositing the bather layer may include a sputter deposition process.

Depositing the adhesion layer may include a vapor deposition process, e.g. a physical vapor deposition (PVD) process, a chemical vapor deposition (CVD) process, a low-pressure CVD (LPCVD) process, a plasma-enhanced CVD (PECVD) process, or a high-density plasma CVD (HPD-CVD) process.

Alternatively, depositing the adhesion layer may include a sputter deposition process.

In various embodiments, depositing the barrier layer and depositing the adhesion layer may be achieved by the same deposition process. In other embodiments, depositing the bather layer and depositing the adhesion layer may be achieved using different deposition processes.

In one embodiment, depositing the bather layer and the adhesion layer may include sputter deposition of the first metallic component and the second metallic component. A concentration ratio between the first and second metallic components may be set in-situ during the sputter deposition.

In further embodiments, depositing the metallization layer may include a pattern plating process.

FIGS. 2A-2D show a method for manufacturing a semiconductor device 210 including a pattern plating process in accordance with one or more embodiments. As shown in FIG. 2A, in one or more embodiments, a barrier layer 212 may be deposited over (e.g. on) a layer (or layer stack) 219. The layer (or layer stack) 219 may, for example, be configured in a similar manner as layer (or layer stack) 119 shown in FIG. 1A and may, for example, include one or more electronic devices (e.g. transistors) 118. The barrier layer 212 may be configured in accordance with one or more embodiments described herein, for example in a similar manner as barrier layer 112 shown in FIG. 1A. In one or more embodiments, an adhesion layer 214 may be deposited over (e.g. on) the barrier layer 212. The adhesion layer 214 may be configured in accordance with one or more embodiments described herein, for example in a similar manner as adhesion layer 114 shown in FIG. 1A. In one or more embodiments, a seed layer 221 may be deposited over (e.g. on) the adhesion layer 214, as shown. The seed layer 221 may be optional.

Subsequently, a metallization layer 216 may be deposited using a pattern plating process. The pattern plating process may include: depositing a mask layer 220 over (e.g. on) the adhesion layer 214 (or over (e.g. on) the seed layer 221, if present) (see FIG. 2A); removing a part of the mask layer 220 to expose a part of the adhesion layer 214 (or seed layer 221, if present) (see FIG. 2B), in other words, patterning the mask layer 220 to form a patterned mask layer 220 that exposes one or more portions of the adhesion layer 214 (or seed layer 221, if present); and electrochemically depositing the metallization layer 216 over the exposed part of the adhesion layer 214 (or seed layer 221, if present) (see FIG. 2C). After depositing the metallization layer 216, one or more remaining portions of the mask layer 220 may be removed, and one or more portions of the adhesion layer 214 and the barrier layer 212 (and the optional seed layer 221 over the adhesion layer 214, if present) below the remaining parts of the mask layer 220 may be removed (see FIG. 2D). Thus, one or more portions of the layer (or layer stack) 219 may, for example, be exposed, as shown.

In one or more embodiments, the material of the mask layer 220 may be selected from a group of materials, the group consisting of: a resist material, an imide material, a polyimide material, an epoxy material, and benzocyclobutene.

The material of the mask layer 220 may include or may be a photoresist, e.g. a positive or a negative photoresist.

In one or more embodiments, removing a part of the mask layer 220 (patterning the mask layer 220) may include exposing the photoresist (subjecting the photoresist to light) and subsequently developing the photoresist or etching the photoresist (resist stripping).

In one or more embodiments, removing the one or more portions of the adhesion layer 214 and the bather layer 212 (and the optional seed layer 221) below the one or more remaining portions of the mask layer 220 may include or may be achieved by etching, for example wet etching.

As shown in FIG. 2D, a semiconductor device 210 (e.g. power semiconductor device) may be provided including a thick metallization (e.g. thick power metal line) 216 disposed over a bather layer 212, with an adhesion layer 214 in-between that may increase adhesion between the metallization 216 and the bather layer 212 and may thus prevent delamination of the metallization layer 216 under e.g. thermal cycling stress.

While various aspects of this disclosure have been particularly shown and described with reference to specific embodiments, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

What is claimed is:

1. A semiconductor device, comprising:
a barrier layer;
an adhesion layer disposed over the barrier layer;
a metallization layer disposed over the adhesion layer,
wherein the metallization layer is part of a final metallization level of the semiconductor device.

2. The semiconductor device of claim 1, wherein the metallization layer has a thickness of greater than or equal to about 1 μm.

3. The semiconductor device of claim 1, wherein the semiconductor device is configured as a power semiconductor device.

4. The semiconductor device of claim 1, wherein the barrier layer comprises at least one material selected from a group of materials, the group consisting of: a metal, a metal alloy.

5. The semiconductor device of claim 1, wherein the barrier layer comprises a first metallic component and a second metallic component different from the first metallic component.

6. The semiconductor device of claim 5,
wherein the first metallic component of the barrier layer is selected from a group of metallic components, the group consisting of: W, Ta, TaN, Mo; and
wherein the second metallic component of the barrier layer is selected from a group of metallic components, the group consisting of: Ti, Ta, Ni, titanium silicide.

7. The semiconductor device of claim 1, wherein the adhesion layer comprises a material that has a stronger adhesion to the metallization layer than a material of the barrier layer.

8. The semiconductor device of claim 1, wherein the adhesion layer comprises a first metallic component and a second metallic component different from the first metallic component.

9. The semiconductor device of claim 8,
wherein the first metallic component of the adhesion layer is selected from a group of metallic components, the group consisting of: W, Ta, TaN, Mo; and
wherein the second metallic component of the adhesion layer is selected from a group of metallic components, the group consisting of: Ti, Ta, Ni, titanium silicide.

10. The semiconductor device of claim 1,
wherein the barrier layer and the adhesion layer each comprise a first metallic component and a second metallic component,
wherein a concentration of the second metallic component in the adhesion layer is greater than a concentration of the second metallic component in the barrier layer,
wherein an increase in concentration of the second metallic component in a layer increases adhesion of that layer to the metallization layer.

11. The semiconductor device of claim 10,
wherein the first metallic component is selected from a group of metallic components, the group consisting of: W, Ta, TaN, Mo; and
wherein the second metallic component is selected from a group of metallic components, the group consisting of: Ti, Ta, Ni, titanium silicide.

12. The semiconductor device of claim 10,
wherein a concentration of the second metallic component in the barrier layer is greater than zero and less than or equal to about 20 at. %, and
wherein a concentration of the second metallic component in the adhesion layer is greater than about 30 at. %.

13. The semiconductor device of claim 1,
wherein the barrier layer and the adhesion layer comprise WTi, TaTi, or MoTi,
wherein a concentration of Ti in the barrier layer is less than or equal to about 20 at. %, and
wherein a concentration of Ti in the adhesion layer is greater than about 30 at. %.

14. The semiconductor device of claim 1, wherein the barrier layer has a thickness of less than or equal to about 500 nm.

15. The semiconductor device of claim 1, wherein the adhesion layer has a thickness of less than or equal to about 100 nm.

16. A semiconductor device, comprising:
a barrier layer comprising a first metallic component and a second metallic component;
an adhesion layer disposed over the barrier layer and comprising the first metallic component and the second metallic component;
a metallization layer disposed over the adhesion layer,
wherein a concentration of the second metallic component in the adhesion layer is greater than a concentration of the second metallic component in the barrier layer.

17. The semiconductor device of claim 16, wherein an increase in concentration of the second metallic component in a layer increases adhesion of that layer to the metallization layer.

18. The semiconductor device of claim 16,
wherein the first metallic component is selected from a group of metallic components, the group consisting of: W, Ta, TaN, Mo; and
wherein the second metallic component is selected from a group of metallic components, the group consisting of: Ti, Ta, Ni, titanium silicide.

19. The semiconductor device of claim 16,
wherein the concentration of the second metallic component in the barrier layer is greater than zero and less than or equal to about 20 at. %, and
wherein the concentration of the second metallic component in the adhesion layer is greater than about 30 at. %.

20. The semiconductor device of claim 16,
wherein the concentration of the second metallic component in the barrier layer is in the range from about 10 at. % to about 20 at. %, and
wherein the concentration of the second metallic component in the adhesion layer is in the range from about 30 at. % to about 40 at. %.

21. The semiconductor device of claim 16,
wherein the first metallic component is W, Ta, or Mo, and
wherein the second metallic component is Ti.

22. A method for manufacturing a semiconductor device, the method comprising:
depositing a barrier layer comprising a first metallic component and a second metallic component;
depositing an adhesion layer over the barrier layer, the adhesion layer comprising the first metallic component and the second metallic component, wherein a concentration of the second metallic component in the adhesion layer is greater than a concentration of the second metallic component in the bather layer; and
depositing a metallization layer over the adhesion layer.

23. The method of claim 22, wherein an increase in concentration of the second metallic component in a layer increases adhesion of that layer to the metallization layer.

24. The method of claim 22, wherein depositing the adhesion layer comprises using the same deposition equipment as used for depositing the bather layer, and varying at least one deposition parameter to obtain an increased concentration of the second metallic component in the adhesion layer compared to the concentration of the second metallic component in the bather layer.

25. The method of claim 22, wherein depositing the metallization layer comprises a pattern plating process.
